(19) United States
(12) Patent Application Publication
(10) Pub. No.: US 2025/0174425 A1
(43) Pub. Date: May 29, 2025

(54) ELECTROMAGNETIC LENS, SCANNING ELECTRON MICROSCOPE, AND MULTI-ELECTRON BEAM INSPECTION APPARATUS

(71) Applicant: NuFlare Technology, Inc., Yokohama-shi (JP)

(72) Inventors: Takahiro MURATA, Zushi-shi (JP); Munehiro OGASAWARA, Hiratsuka-shi (JP)

(73) Assignee: NuFlare Technology, Inc., Yokohama-shi (JP)

(21) Appl. No.: 18/909,190

(22) Filed: Oct. 8, 2024

(30) Foreign Application Priority Data
Nov. 29, 2023 (JP) 2023-202105

(51) Int. Cl. H01J 37/141; H01J 37/28

(52) U.S. Cl. CPC H01J 37/141; H01J 37/28; H01J 2237/1415

(57) ABSTRACT

An electromagnetic lens includes a coil; a yoke including an upper wall on the upstream side along the advancing direction of a primary electron beam passing, outer and inner peripheral walls, and a lower wall where a gap is formed on the downstream side along the primary-electron-beam advancing direction or an inclined wall where a gap is formed on the downstream side along the primary-electron-beam advancing direction, letting the primary electron beam pass through a space surrounded by the inner peripheral wall, and surrounding the coil by the upper wall, the outer and inner peripheral walls, and the lower wall or the inclined wall; and a cover contacting and covering an end surface of the yoke on the downstream side along the primary-electron-beam advancing direction, the end surface including a corner portion on the inner peripheral side, wherein the cover corner portion is formed having a curved surface.

### CROSS-REFERENCE TO RELATED APPLICATION

This application is based upon and claims the benefit of priority from prior Japanese Patent Application No. 2023-202105 filed on Nov. 29, 2023 in Japan, the entire contents of which are incorporated herein by reference.

### BACKGROUND OF THE INVENTION

### Field of the Invention

An embodiment of the present invention relates to an electromagnetic lens, a scanning electron microscope, and a multi-electron beam inspection apparatus. For example, it relates to an electromagnetic lens disposed in a multi-beam inspection apparatus which inspects patterns by using a secondary electron image resulting from irradiation with multiple primary electron beams.

### Description of Related Art

With recent progress in high integration and large capacity of the Large Scale Integrated circuits (LSI), the line width (critical dimension) necessary for circuits of semiconductor elements is becoming increasingly narrower. Since LSI manufacturing needs an enormous production cost, it is essential to improve the yield. However, as typified by 1 gigabit DRAMs (Dynamic Random Access Memories), the size of patterns that make up LSIs becomes the order of nanometers from submicrons. Also, in recent years, with miniaturization of dimensions of LSI patterns formed on a semiconductor wafer, dimensions to be detected as a pattern defect have become extremely small. Therefore, acquiring highly accurate images is needed in order also to inspect defects of ultrafine patterns exposed (transferred) to a semiconductor wafer.

With regard to an inspection apparatus, for example, after focusing multiple primary electron beams onto a substrate to be inspected (inspection target substrate), the inspection apparatus scans the multiple primary electron beams over the inspection target substrate, separates multiple secondary electron beams emitted from the inspection target substrate from the trajectory of the multiple primary electron beams, and leads the separated multiple secondary electron beams to a detector. Then, the detector detects the multiple secondary electron beams in order to obtain a pattern image.

If the acceleration voltage of the inspection apparatus is increased, it becomes possible to reduce aberration due to the optical column. However, if the acceleration voltage is applied as it is to a target object, the dispersion region of a primary electron beam increases, thereby degrading resolution. Then, using the retarding method whereby a negative potential is applied to the surface of the inspection target substrate in order to attenuate the primary electron beams just before reaching the target object, inspection of reduced aberration and high resolution is carried out. Thus, according to the retarding method, beams can pass through the inside of the optical column at a high acceleration to suppress the influence of aberration, and the dispersion region of a primary electron beam can be reduced by decreasing the speed just before the target object by applying a negative voltage to the target object, and therefore, resolution can be improved. However, in this process, there is a problem in that, if the distance between the lower surface of the objective lens and the surface of the inspection target substrate is reduced while an electric field is being generated between the objective lens and the inspection target substrate, an electric discharge may occur due to an electric field concentration at the corner of the yoke end of the objective lens.

Then, for avoiding the electric discharge, there is disclosed a method of disposing a control electrode plate between the objective lens and the target object (e.g., refer to Japanese Patent Application Laid-open (JP-A) No. 2003-168385).

### BRIEF SUMMARY OF THE INVENTION

According to one aspect of the present invention, an electromagnetic lens includes
a coil;
a yoke, made of magnetic material, configured to include an upper wall on an upstream side with respect to an advancing direction of a primary electron beam passing, an outer peripheral wall, an inner peripheral wall, and one of a lower wall in which a gap is formed on a downstream side with respect to the advancing direction of the primary electron beam and an inclined wall in which a gap is formed on a downstream side with respect to the advancing direction of the primary electron beam, configured to let the primary electron beam pass through a space surrounded by the inner peripheral wall, and configured to surround the coil by the upper wall, the outer peripheral wall, the inner peripheral wall, and the one of the lower wall and the inclined wall; and
a cover, made of a non-magnetic conductor, configured to contact and cover an end surface of the yoke on the downstream side with respect to the advancing direction of the primary electron beam, the end surface including a corner portion on an inner peripheral side, wherein a corner portion of the cover is formed to have a curved surface.

According to another aspect of the present invention, a scanning electron microscope includes
an electromagnetic lens configured to include
   a coil,
   a yoke, made of magnetic material, which includes an upper wall on an upstream side with respect to an advancing direction of a primary electron beam passing, an outer peripheral wall, an inner peripheral wall, and one of a lower wall in which a gap is formed on a downstream side with respect to the advancing direction of the primary electron beam and an inclined wall in which a gap is formed on a downstream side with respect to the advancing direction of the primary electron beam, which is configured to let the primary electron beam pass through a space surrounded by the inner peripheral wall, and which surrounds the coil by the upper wall, the outer peripheral wall, the inner peripheral wall, and the one of the lower wall and the inclined wall, and
   a cover, made of a non-magnetic conductor, which contacts and covers an end surface of the yoke on the downstream side with respect to the advancing direction of the primary electron beam, the end surface of the yoke including a corner portion on an inner peripheral side, wherein the corner portion of the cover is formed to have a curved surface;
a stage configured to place thereon a target object which is to be irradiated with the primary electron beam having passed through the electromagnetic lens; and
a detector configured to detect a secondary electron beam emitted from the target object.

According to yet another aspect of the present invention, an electron beam inspection apparatus includes
an electromagnetic lens configured to include
   a coil,
   a yoke, made of magnetic material, which includes an upper wall on an upstream side with respect to an advancing direction of a primary electron beam passing, an outer peripheral wall, an inner peripheral wall, and one of a lower wall in which a gap is formed on a downstream side with respect to the advancing direction of the primary electron beam and an inclined wall in which a gap is formed on a downstream side with respect to the advancing direction of the primary electron beam, which is configured to let the primary electron beam pass through a space surrounded by the inner peripheral wall, and which surrounds the coil by the upper wall, the outer peripheral wall, the inner peripheral wall, and the one of the lower wall and the inclined wall, and
   a cover, made of a non-magnetic conductor, which contacts and covers an end surface of the yoke on the downstream side with respect to the advancing direction of the primary electron beam, the end surface of the yoke including a corner portion on an inner peripheral side, wherein the corner portion of the cover is formed to have a curved surface;
a stage configured to place thereon a target object which is to be irradiated with the primary electron beam having passed through the electromagnetic lens; and
a detector configured to detect a secondary electron beam emitted from the target object.

### BRIEF DESCRIPTION OF THE DRAWINGS

FIG. 1 is an illustration showing an example of a configuration of a pattern inspection apparatus according to a first embodiment;

FIG. 2 is a top view showing an example of a configuration of a shaping aperture array substrate according to the first embodiment;

FIG. 3 is an illustration showing an example of an objective lens according to a comparative example of the first embodiment;

FIG. 4 is an illustration showing an example of an objective lens according to the first embodiment;

FIG. 5 is an illustration showing another example of an objective lens according to the first embodiment;

FIG. 6 is an illustration showing an analysis result by simulation of an electric field at the yoke end in the state without covering according to a comparative example of the first embodiment;

FIG. 7 is an illustration showing an analysis result by simulation of an electric field at the yoke end in the state with covering according to the first embodiment;

FIG. 8 is an illustration for describing an inspection region and an inspection method according to the first embodiment; and

FIG. 9 is a diagram showing an example of an internal configuration of a comparison circuit according to the first embodiment.

### DETAILED DESCRIPTION OF THE INVENTION

Embodiments below provide an electromagnetic lens and an apparatus which are capable of suppressing an electric discharge between an objective lens and a target object.

Embodiments below describe multiple electron beams as an example of an electron beam. In other words, multiple primary electron beams are described as an example of a primary electron beam, and multiple secondary electron beams are described as an example of a secondary electron beam. The electron beam is not limited to multiple electron beams, and thus, a single electron beam may also be used. Further, Embodiments below describe an electron beam inspection apparatus as an example of an electron beam irradiation apparatus. The electron beam irradiation apparatus is not limited to the inspection apparatus, and may be a scanning electron microscope or an electron beam image acquisition apparatus, for example.

### First Embodiment

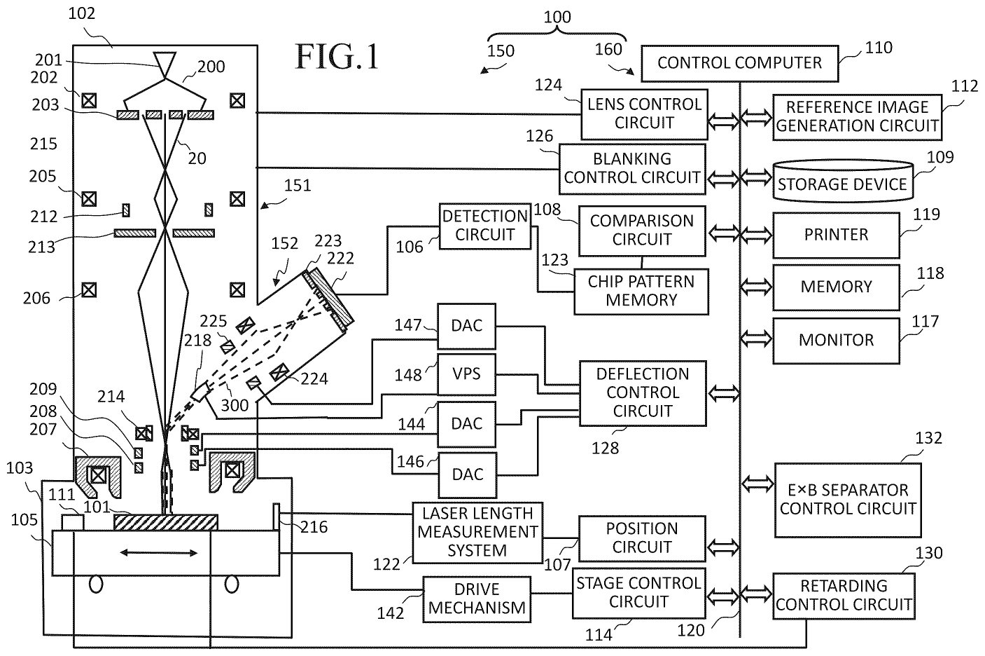

FIG. 1 is an illustration showing an example of a configuration of a pattern inspection apparatus according to a first embodiment. In FIG. 1, an inspection apparatus 100 which inspects patterns formed on a substrate is an example of a multi-electron beam inspection apparatus. Also, the inspection apparatus 100 is an example of an electron beam irradiation apparatus, and an example of a scanning electron microscope or an electron beam image acquisition apparatus. The inspection apparatus 100 includes an image acquisition mechanism 150 and a control system circuit 160 (control unit). The image acquisition mechanism 150 includes an electron beam column 102 (electron optical column), an inspection chamber 103, a detection circuit 106, a chip pattern memory 123, a stage drive mechanism 142, and a laser length measurement system 122. In the electron beam column 102, there are disposed an electron gun 201, an electromagnetic lens 202, an electromagnetic lens 205, a collective deflector 212, a limiting aperture substrate 213, an electromagnetic lens 206, an E×B separator 214 (separator), an electromagnetic lens 207 (objective lens), deflectors 208 and 209, a deflector 218, a deflector 225, an electromagnetic lens 224, and a multi-detector 222. During the operation of the inspection apparatus 100, the insides of the electron beam column 102 and the inspection chamber 103 are evacuated by a vacuum pump, etc. (not shown) to be adjusted in a vacuum state.

A primary electron optical system 151 (illumination optical system) is composed of the electron gun 201, the electromagnetic lens 202, the electromagnetic lens 205, the collective deflector 212, the limiting aperture substrate 213, the electromagnetic lens 206, the E×B separator 214 (separator), the electromagnetic lens 207, and the deflectors 208 and 209. A secondary electron optical system 152 (detection optical system) is composed of the electromagnetic lens 207, the deflectors 208 and 209, the E×B separator 214, the deflector 218, the deflector 225, and the electromagnetic lens 224.

In the case of FIG. 1, although the yokes individually surrounding the electromagnetic lenses 202, 205, 206, and 224, other than the electromagnetic lens 207, and surrounding the E×B separators 214 are not shown, it should be understood that such yokes are obviously arranged. The shape of the yoke may be different from each other depending on the electromagnetic lens, or may be the same with respect to at least two electromagnetic lenses.

The multi-detector 222 includes a plurality of detection elements arranged in an array.

In the inspection chamber 103, there is disposed a stage 105 movable at least in the x and y directions. On the stage 105, a substrate 101 (target object) to be inspected is placed. The substrate 101 may be an exposure mask substrate, or a semiconductor substrate such as a silicon wafer. In the case of the substrate 101 being a semiconductor substrate, a plurality of chip patterns (wafer die) are formed on the semiconductor substrate. In the case of the substrate 101 being an exposure mask substrate, a chip pattern is formed on the exposure mask substrate. The chip pattern is composed of a plurality of figure patterns. When the chip pattern formed on the exposure mask substrate is exposed and transferred a plurality of times onto the semiconductor substrate, a plurality of chip patterns (wafer die) are formed on the semiconductor substrate. The substrate 101 is placed, with its pattern-forming surface facing upward, on the stage 105, for example. Further, on the stage 105, there is disposed a mirror 216 which reflects a laser beam for measuring a laser length emitted from a laser length measurement system 122 arranged outside the inspection chamber 103. Furthermore, on the XY stage 105, a mark 111 adjusted to be flush in height with the surface of the substrate 101 is arranged. For example, a cross pattern is formed as the mark 111.

The multi-detector 222 is connected, at the outside of the electron beam column 102, to a detection circuit 106. The detection circuit 106 is connected to the chip pattern memory 123.

In the control system circuit 160, a control computer 110 which controls the whole of the inspection apparatus 100 is connected, through a bus 120, to a position circuit 107, a comparison circuit 108, a reference image generation circuit 112, a stage control circuit 114, a lens control circuit 124, a blanking control circuit 126, a deflection control circuit 128, a retarding control circuit 130, an E×B separator control circuit 132, a storage device 109 such as a magnetic disk drive, a monitor 117, a memory 118, and a printer 119. The deflection control circuit 128 is connected to DAC (digital-to-analog conversion) amplifiers 144, 146, and 147, and to a direct current power supply 148. The DAC amplifier 146 is connected to the deflector 208, and the DAC amplifier 144 is connected to the deflector 209. The direct current power supply 148 is connected to the deflector 218. The DAC amplifier 147 is connected to the deflector 225.

The chip pattern memory 123 is connected to the comparison circuit 108. The stage 105 is driven by a drive mechanism 142 under the control of the stage control circuit 114. In the drive mechanism 142, for example, a drive system such as a three (x-, y-, and θ-) axis motor driving in the directions of x, y, and θ in the stage coordinate system is configured, and therefore, the stage 105 can be moved in the x, y, and θ directions. A step motor, for example, can be used as each of these x, y, and θ motors (not shown). The stage 105 is movable in the horizontal direction and the rotation direction by the x-, y-, and θ-axis motors. The movement position of the stage 105 is measured by the laser length measurement system 122, and supplied (transmitted) to the position circuit 107. Based on the principle of laser interferometry, the laser length measurement system 122 measures the position of the stage 105 by receiving a reflected light from the mirror 216. With respect to the stage coordinate system, the x, y, and θ directions of the primary coordinate system are set, for example, to a plane perpendicular to the optical axis of multiple primary electron beams 20.

The electromagnetic lenses 202, 205, 206, 207, and 224 are controlled by the lens control circuit 124.

The collective deflector 212 is composed of two or more electrodes (or poles), and each electrode is controlled by the blanking control circuit 126 through a DAC amplifier (not shown). The deflector 209 is composed of four or more electrodes (or poles), and each electrode is controlled by the deflection control circuit 128 through the DAC amplifier 144. The deflector 208 is composed of four or more electrodes (or poles), and each electrode is controlled by the deflection control circuit 128 through the DAC amplifier 146. The deflector 225 is composed of four or more electrodes (or poles), and each electrode is controlled by the deflection control circuit 128 through the DAC amplifier 147.

The deflector 218 (vendor) is, for example, an arc-shaped bending tube, composed of four or more electrodes (or poles), and controlled, for each electrode, by the deflection control circuit 128 through the direct current power supply 148. Alternatively, the deflector 218 may be a tablet, composed of four or more electrodes (or poles), and controlled, for each electrode, by the deflection control circuit 128 through the direct current power supply 148.

The E×B separator 214 is controlled by the E×B separator control circuit 132.

The retarding control circuit 130 applies a retarding electric potential to the surface of the substrate 101 so that the multiple primary electron beams 20 can obtain a desired landing energy at the surface of the substrate 101. Generally, a negative potential is applied as the retarding electric potential.

To the electron gun 201, there is connected a high voltage power supply circuit (not shown). The high voltage power supply circuit applies an acceleration voltage between a filament (not shown) and an extraction electrode (not shown) in the electron gun 201. In addition to the applying the acceleration voltage, a predetermined voltage is applied to the extraction electrode, and the cathode is heated to a predetermined temperature, and thereby, electrons from the cathode are accelerated to be emitted as an electron beam 200.

FIG. 1 shows configuration elements necessary for describing the first embodiment. Other configuration elements generally necessary for the inspection apparatus 100 may also be included therein.

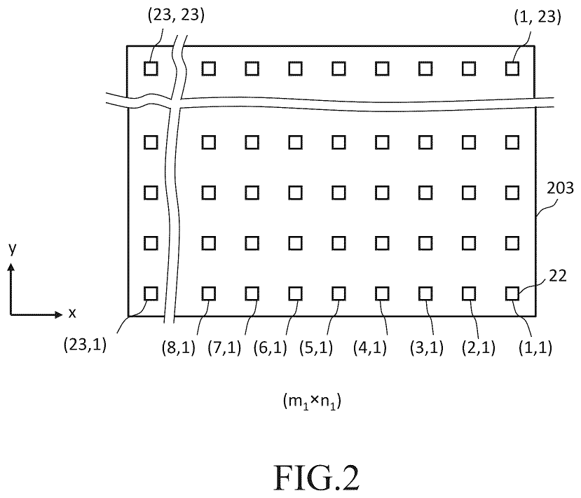

FIG. 2 is a top view showing an example of a configuration of a shaping aperture array substrate according to the first embodiment. As shown in FIG. 2, holes (openings) 22 of m₁ columns wide (in the x direction) and n₁ rows long (in the y direction), where each of m₁ and n₁ is an integer of 2 or more, are two-dimensionally formed in the x and y directions at a predetermined arrangement pitch in the shaping aperture array substrate 203. In the case of FIG. 2, 23×23 holes (openings) 22 are formed. Each of the holes 22 is a circle with the same dimension and shape. Alternatively, as shown in FIG. 2, each of the holes 22 may be a rectangle (including a square) having the same dimension and shape. The multiple primary electron beams 20 are formed by letting portions of the electron beam 200 individually pass through a corresponding one of a plurality of holes 22. The shaping aperture array substrate 203 serves as an example of a multiple beam forming mechanism which forms the multiple primary electron beams 20.

The electron beam 200 emitted from the electron gun 201 (emission source) is refracted by the electromagnetic lens 202, and illuminates the whole of the shaping aperture array substrate 203. As shown in FIG. 2, a plurality of holes 22 (openings) are formed in the shaping aperture array substrate 203. The region including all the plurality of holes 22 is irradiated with the electron beam 200. The multiple primary electron beams 20 are formed by letting portions of the electron beam 200 applied to the positions of the plurality of holes 22 individually pass through a corresponding one of the plurality of holes 22 in the shaping aperture array substrate 203.

The formed multiple primary electron beams 20 are individually refracted by the electromagnetic lenses 205 and 206, and, while repeating forming an intermediate image and a crossover, travel to the electromagnetic lens 207 (objective lens) passing through the E×B separator 214 arranged in the intermediate image plane of each beam of the multiple primary electron beams 20.

When the multiple primary electron beams 20 are incident on the electromagnetic lens 207 (objective lens), the electromagnetic lens 207 focuses the multiple primary electron beams 20 onto the substrate 101. The multiple primary electron beams 20 having been focused on the substrate 101 (target object) by the electromagnetic lens 207 are collectively deflected by the deflectors 208 and 209 to irradiate respective beam irradiation positions on the substrate 101. In the case where all of the multiple primary electron beams 20 are collectively deflected by the collective blanking deflector 212, they deviate from the hole in the center of the limiting aperture substrate 213 and all of them are blocked by the limiting aperture substrate 213. By contrast, the multiple primary electron beams 20 which were not deflected by the collective blanking deflector 212 pass through the hole in the center of the limiting aperture substrate 213 as shown in FIG. 1. Blanking control is provided by On/Off of the collective blanking deflector 212, and thus On/Off of the multiple beams is collectively controlled. In this way, the limiting aperture substrate 213 blocks the multiple primary electron beams 20 which were deflected to be in an “Off state” by the collective blanking deflector 212. Then, the multiple primary electron beams 20 for image acquisition are formed by the beams having been made during a period from becoming “beam On” to becoming “beam Off” and having passed through the limiting aperture substrate 213.

When desired positions on the substrate 101 are irradiated with the multiple primary electron beams 20, a flux of secondary electrons (multiple secondary electron beams 300), including reflected electrons, each corresponding to each beam of the multiple primary electron beams 20 is emitted from the substrate 101 due to the irradiation with the multiple primary electron beams 20.

The multiple secondary electron beams 300 emitted from the substrate 101 pass through the electromagnetic lens 207 and travel to the E×B separator 214. The E×B separator 214 includes a plurality of at least two magnetic poles each having a coil, and a plurality of at least two electrodes (poles). For example, the E×B separator 214 includes four magnetic poles (electromagnetic deflection coils) whose phases are mutually shifted by 90°, and four electrodes (electrostatic deflection electrodes) whose phases are also mutually shifted by 90°. For example, by setting two opposing magnetic poles to be an N pole and an S pole, a directive magnetic field is generated by these plurality of magnetic poles. Also, for example, by applying electrical potentials V, whose signs are opposite to each other, to the two opposing electrodes, a directive electric field is generated by these plurality of electrodes. Specifically, the E×B separator 214 generates an electric field and a magnetic field to be orthogonal to each other in a plane perpendicular to the traveling direction of the center beam (i.e., trajectory central axis) of the multiple primary electron beams 20. The electric field exerts a force in a fixed direction regardless of the traveling direction of electrons. In contrast, the magnetic field exerts a force according to Fleming's left-hand rule. Therefore, the direction of the force acting on (applied to) electrons can be changed depending on the entering (or “traveling”) direction of electrons. With respect to the multiple primary electron beams 20 entering the E×B separator 214 from above, since the forces due to the electric field and the magnetic field cancel each other out, the beams 20 travel straight downward. In contrast, with respect to the multiple secondary electron beams 300 entering the E×B separator 214 from below, since both the forces due to the electric field and the magnetic field are exerted in the same direction, the beams 300 are bent obliquely upward, and separated from the trajectory of the multiple primary electron beams 20.

The multiple secondary electron beams 300 having been bent obliquely upward are further bent by the deflector 218, and projected onto the multi-detector 222 while being refracted by the electromagnetic lens 224.

A detector aperture array substrate 223 is arranged on the multi-detector 222. The multi-detector 222 detects the projected multiple secondary electron beams 300 having passed through the openings of the detector aperture array substrate 223. At the detection surface of the multi-detector 222, since each beam of the multiple primary electron beams 20 collides with a detection element corresponding to each secondary electron beam of the multiple secondary electron beams 300, an amplified generation of electrons occurs, and secondary electron image data is generated for each pixel. An intensity signal detected by the multi-detector 222 is output to the detection circuit 106. A sub-irradiation region on the substrate 101, in which the beam concerned itself is located and which is surrounded with the beam's x-direction beam pitch and y-direction beam pitch, is irradiated and scanned by each primary electron beam.

Further, in order to follow the continuous movement of the stage 105, a tracking control is performed by deflecting the multiple primary electron beams 20 by the deflectors 208 and 209. Due to the deflecting the beams by the tracking control and scanning the multiple primary electron beams 20 over the substrate 101, the emission position of the secondary electron beam corresponding to each primary electron beam changes every second. Therefore, if this goes on, each secondary electron beam deviates from a corresponding detection element. Then, by collectively performing swing-back deflection of the multiple secondary electron beams 300 by the deflector 225, the position of each secondary electron beam on the detection surface of the multi-detector 222 can be made unchanged. Thereby, each secondary electron beam can enter its corresponding detection element.

As described above, acquiring a secondary electron image is carried out by applying the multiple primary electron beams 20 to the substrate 101, and detecting, by the multi-detector 222, the multiple secondary electron beams 300 emitted from the substrate 101 due to the irradiation with the multiple primary electron beams 20.

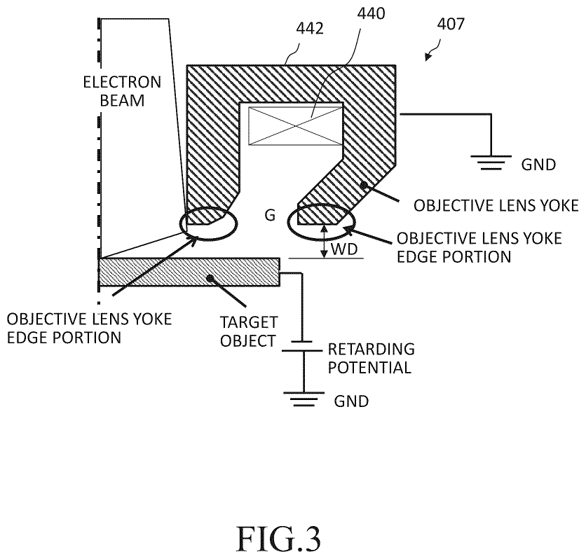

FIG. 3 is an illustration showing an example of an objective lens according to a comparative example of the first embodiment. The comparative example in FIG. 3 shows an electromagnetic lens 407 where a coil 440 is surrounded by a yoke 442. The example of FIG. 3 shows a sectional view of the right half against the trajectory central axis of an electron beam. The left half is not illustrated. The comparative example shows a case of the objective lens 407 of a semi-in-lens system where the gap G of the objective lens 407 faces downward and the target object is disposed below the objective lens 407. The semi-in-lens system can achieve a high resolution equivalent to an electromagnetic lens of an in-lens system by lessening the distance (WD: working distance) between the lower surface of the objective lens and the target object. Further, similarly to an electromagnetic lens of an out-lens system, an electromagnetic lens of a semi-in-lens system can be used for a target object which is larger than the inner peripheral diameter of the yoke of the electromagnetic lens. In that case, a negative retarding potential is applied to the target object, and a ground (GND) potential is applied to the yoke 442 of the electromagnetic lens. Therefore, an electric field is generated between the lower surface of the objective lens and the target object. At this time, an electron beam is subject to an influence of aberration depending on machining accuracy of parts and assembly accuracy of the apparatus. Therefore, generally, as much as possible, it is tried to avoid any influence of machining accuracy and assembly accuracy, but since there is a mechanical limit, correction is performed using, for example, a deflection electromagnetic lens, etc. In edge processing of parts, it is enormously difficult to uniformly perform R processing and chamfering while keeping desired dimensions. In consideration of the influence on aberration, unevenness on the circumference poses a big problem. Thus, it is necessary to take the influence of extra aberration into consideration. Then, by forming a shape without performing chamfering and R processing of the corner (edge portion) of the yoke end surface of the objective lens, the influence of aberration can be reduced. However, as a result, there occurs a problem in that an electric field is concentrated at the corner of the yoke end surface and an electric discharge may occur.

Then, in the first embodiment, the electric field concentration at the corner of the yoke end surface is avoided or reduced. It will be described below specifically.

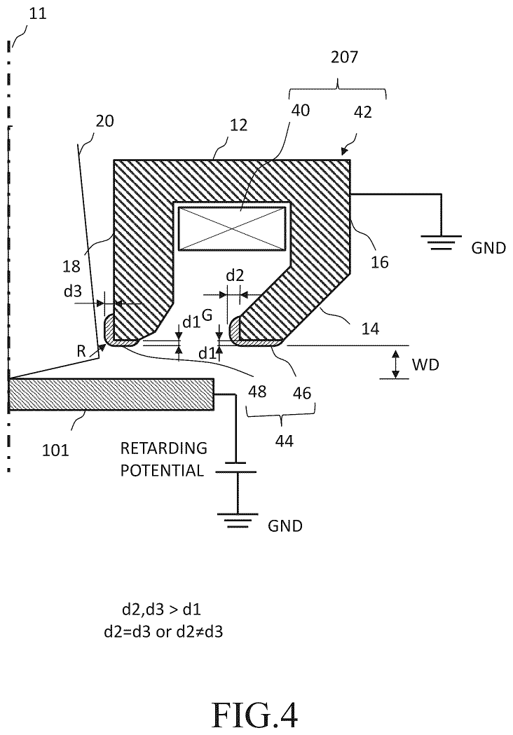

FIG. 4 is an illustration showing an example of an objective lens according to the first embodiment. In FIG. 4, the electromagnetic lens 207 serving as an objective lens includes a coil 40, a yoke (also called a pole piece) 42, and a cover 44. The example of FIG. 4 shows a sectional view of the right half against a trajectory central axis 11 of the multiple primary electron beams 20. The left half is not illustrated.

The coil 40 is annularly arranged such that it surrounds the passage region of the multiple primary electron beams 20.

The yoke 42 is made of magnetic material, and further, made of conductor. The yoke 42 includes an upper wall 12, an outer peripheral wall 16, an inner peripheral wall 18, and an inclined wall 14 each of which has a certain thickness. The yoke 42 is annularly arranged so that it may surround the passage region of the multiple primary electron beams 20, and it surrounds the coil 40. That is, the coil 40 is surrounded by the upper wall 12, the outer peripheral wall 16, the inner peripheral wall 18, and the inclined wall 14. Further, the yoke 42 is configured such that the multiple primary electron beams 20 pass through the space surrounded by the inner peripheral wall 18. The upper wall 12 is arranged on the upstream side with respect to the advancing direction of the passing multiple primary electron beams 20.

The upper wall 12 and the inclined wall 14 are disk-shaped and concentric to have an aperture at the center. The outer peripheral wall 16 and the inner peripheral wall 18 are tubular and concentric to have diameters of different sizes from each other. The distance between the upper wall 12 and the inclined wall 14 is set to be capable of interposing the coil 40 therebetween. The distance between the outer peripheral wall 16 and the inner peripheral wall 18 is set to be capable of interposing the coil 40 therebetween.

In the example of FIG. 4, the inclined wall 14 is formed to be continuous from the end of the outer peripheral wall 16, and its section extends aslant towards the inner peripheral side in a tapering manner towards the downstream side with respect to the advancing direction of the multiple primary electron beams 20. The gap G is formed between the end of the inner peripheral wall 18, on the downstream side with respect to the advancing direction of the multiple primary electron beams 20, and the end of the inclined wall 14, on the downstream side with respect to the advancing direction of the multiple primary electron beams 20. In other words, the inclined wall 14 forms the gap G on the downstream side with respect to the advancing direction of the multiple primary electron beams 20. In the case of FIG. 4, the end surface of the inner peripheral wall 18, on the downstream side with respect to the advancing direction of the multiple primary electron beams 20, and the end surface of the inclined wall 14, on the downstream side with respect to the advancing direction of the multiple primary electron beams 20, are arranged to be flush at the same height.

According to the first embodiment, as shown in FIG. 4, an objective lens of a semi-in-lens system is configured where the gap G of the objective lens 207 faces downward and the target object 101 is disposed below the objective lens 207. As described above, the semi-in-lens system can obtain an image of high resolution equivalent to that of an electromagnetic lens of an in-lens system by lessening the distance (WD: working distance) between the lower surface of the objective lens and the target object. Further, similarly to an electromagnetic lens of an out-lens system, an electromagnetic lens of a semi-in-lens system can be used for a target object which is larger than the inner peripheral diameter of a yoke of an electromagnetic lens. In that case, a negative retarding potential is applied to the target object 101, and a ground (GND) potential is applied to the yoke 42. Therefore, an electric field is generated between the lower surface of the objective lens and the target object. Further, in order to reduce the influence of aberration, chamfering and R processing of the end surface corner (edge portion) of the yoke 42 of the objective lens 207 are not performed. However, if this goes on, an electric field is concentrated at the corner of the yoke end surface as described with reference to FIG. 3. Then, according to the first embodiment, the yoke end surface is covered with a cover 44.

The cover 44 contacts and covers the end surface of the yoke 42 on the downstream side with respect to the advancing direction of the multiple primary electron beams 20, the end surface of the yoke 42 including the corner portion on the inner peripheral side. The cover 44 is made of non-magnetic conductor. For example, it is preferable to use titanium (Ti), gold (Ag), or beryllium copper (BeCu). In the example of FIG. 4, since the corner portion of the end surface of the yoke 42, on the outer peripheral side and on the downstream side, is obtuse sufficiently larger than 90°, the electric field concentration does not occur easily. Therefore, in the case of FIG. 4, with respect to both the corner portions of the end surfaces on the downstream side, the corner portion on the inner peripheral side, which is formed at about 90°, is covered with the cover 44. If the angles of both the corner portions are 90° or less, or not sufficiently larger than 90° (e.g., 120° or less), it is preferable to cover both the corner portions with the cover 44.

The cover 44 is individually arranged on the both sides of the gap G. Specifically, the cover 44 includes a covering member 48 (the first covering member) which covers the end surface of the inner peripheral wall 18 on the downstream side with respect to the advancing direction of the multiple primary electron beams 20, the end surface of the inner peripheral wall 18 including the inner peripheral side corner portion at the downstream side end with respect to the advancing direction of the multiple primary electron beams 20, and a covering member 46 (the second covering member) which covers the end surface of the inclined wall 14 on the downstream side with respect to the advancing direction of the multiple primary electron beams 20, the end surface of the inclined wall 14 including the inner peripheral side corner portion at the downstream side end with respect to the advancing direction of the multiple primary electron beams 20. Preferably, the covering member 48 is pressed in and fixed to the end surface of the inner peripheral wall 18. Similarly, the covering member 46 is preferably pressed in and fixed to the end surface of the inclined wall 14. By this, a plurality of screws and stays (supporting members) for connecting the covering members 46 and 48 which cause aberration can be unnecessary. Since the covering members 46 and 48 are just arranged at the end surfaces including the corner portions on the inner peripheral side of the yoke 42, at the downstream side end, it can prevent the mirror 216 from being interfered even when the stage moves, for example.

The corner portion of the cover 44 is formed to have a curved surface. That is, each of the corner portions of the two covering members 46 and 48 is a curved surface. The radius of curvature of the curved surface at the corner portion of the cover 44 is set such that the electric field strength at the corner portion is a threshold value or less in the state where a ground potential has been applied to the yoke 42 and a retarding potential has been applied to the substrate 101. As the threshold value, it is preferable to use 6 kV/mm or less.

The cover 44 covers the end surfaces of the yoke 42, on the downstream side with respect to the advancing direction of the multiple electron beams and opposite to the substrate, and covers portions of the inner peripheral surfaces continuous from the downstream side end surfaces and opposite to the trajectory central axis of the multiple electron beams. Thus, the inner peripheral side corner portions at the downstream side end surface are covered. It is preferable that the thickness of each of d2 and d3 (the first thickness) which covers a portion of the inner peripheral surface is thicker than the thickness d1 (the second thickness) which covers the downstream side end surface. Thereby, while the thickness d1 of the cover 44 which covers the downstream side end surfaces is decreased, the radius of curvature, R, of the curved surface of the corner portion can be increased. The thicknesses d2 and d3 may the same or different from each other. For increasing the radius of curvature, R, of the curved surface of the corner portion, it is necessary to increase the thickness d1 or at least one of the thicknesses d2 and d3 in accordance with the size of the radius of curvature, R. If the thickness d1 is increased, since the distance against the substrate 101 becomes decreased, the electric field strength at the yoke end surface becomes increased. Consequently, an electric discharge may easily occur. In contrast, by increasing the thicknesses d2 and d3 depending on decrease of the thickness d1, it is possible to prevent the electric field strength at the yoke end surface from increasing. Therefore, the risk of electric discharge can be reduced. If the thickness d1 of the cover 44 which covers the downstream side end surface is increased, the WD becomes decreased in accordance with the increase. By making each of the thicknesses d2 and d3 (the first thickness) which covers a portion of the inner peripheral surface thicker than the thickness d1 (the second thickness) which covers the downstream side end surface, it is possible to increase the radius of curvature, R, of the curved surface of the corner portion while maintaining an allowable WD. The electric field concentration can be further mitigated by increasing the radius of curvature of the curved surface of the corner portion. Preferably, each of the thicknesses of the two covering members 46 and 48, at the downstream side end surface, is set to d1.

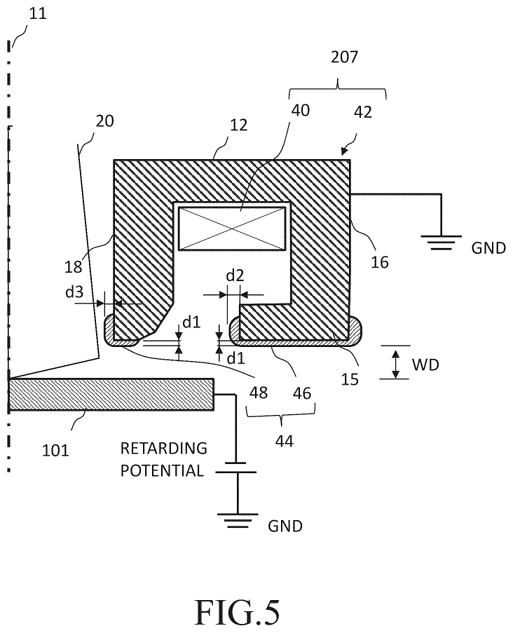

FIG. 5 is an illustration showing another example of an objective lens according to the first embodiment. The example of FIG. 5 shows a sectional view of the right half against the trajectory central axis 11 of the multiple primary electron beams 20. The left half is not illustrated. The example of FIG. 5 is the same as FIG. 4 except that a lower wall 15 is arranged instead of the inclined wall 14. The coil 40 is surrounded by the upper wall 12, the outer peripheral wall 16, the inner peripheral wall 18, and the lower wall 15. The lower wall 15 is a concentric disk shape having an aperture at the center. The gap G is formed between the end portion of the inner peripheral wall 18, on the downstream side with respect to the advancing direction of the multiple primary electron beams 20, and the end portion of the lower wall 15, at the inner peripheral side. In other words, the lower wall 15 forms the gap G on the downstream side with respect to the advancing direction of the multiple primary electron beams 20. In the case of FIG. 5, the end surface of the inner peripheral wall 18, on the downstream side with respect to the advancing direction of the multiple primary electron beams 20, and the surface of the lower wall 15, on the downstream side with respect to the advancing direction of the multiple primary electron beams 20, are preferably arranged to be flush at the same height.

The cover 44 includes the covering member 48 (the first covering member) which covers the end surface including the inner peripheral side corner portion of the inner peripheral wall 18, at the downstream side end with respect to the advancing direction of the multiple primary electron beams 20, and the covering member 46 (the second covering member) which covers the end surface including the inner peripheral side corner portion of the lower wall 15, at the downstream side end with respect to the advancing direction of the multiple primary electron beams 20. In the case of FIG. 5, similarly to FIG. 4, it is preferable that the thickness of each of d2 and d3 (the first thickness) which covers a portion of the inner peripheral surface is thicker than the thickness d1 (the second thickness) which covers the downstream side end surface. In the case of FIG. 5, preferably, the covering member 46 covers, with the thickness d2, a portion of the outer peripheral surface continuous from the downstream side end surface of the lower wall 15.

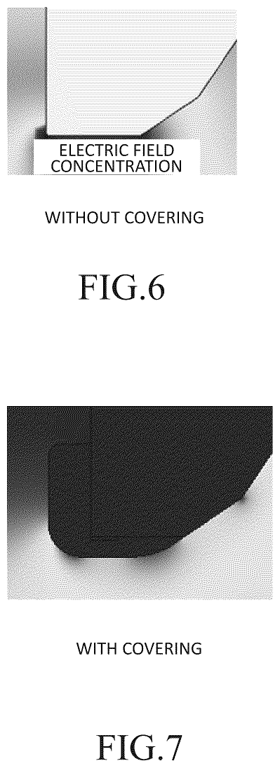

FIG. 6 is an illustration showing an analysis result by simulation of an electric field at the yoke end in the state without covering according to a comparative example of the first embodiment.

FIG. 7 is an illustration showing an analysis result by simulation of an electric field at the yoke end in the state with covering according to the first embodiment. As shown in FIG. 6, in the state of the yoke end without covering, concentration of an electric field occurs, and the electric field strength is about the maximum 13 kV/mm under predetermined conditions. In contrast, as shown in FIG. 7, in the state of the yoke end with the cover 44, the electric field concentration is greatly mitigated, thereby suppressing the electric field strength to 6 kV/mm or less being a threshold.

Then, using the electromagnetic lens 207 capable of avoiding or reducing electric discharge, inspection of the substrate 101 is executed.

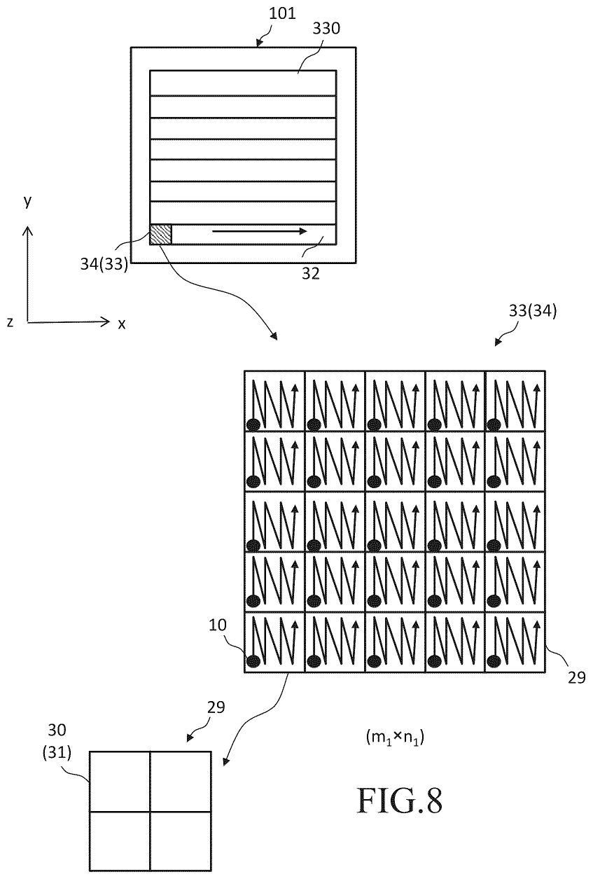

FIG. 8 is an illustration for describing an inspection region and an inspection method according to the first embodiment. As shown in FIG. 8, in the case of the substrate 101 being a mask substrate, an inspection region 330 of the mask substrate is divided, for example, in the y direction into a plurality of stripe regions 32 by a predetermined width. The scanning operation by the image acquisition mechanism 150 is carried out for each stripe region 32, for example. The operation of scanning the stripe region 32 advances relatively in the x direction while the stage 105 is moved in the −x direction, for example. Each stripe region 32 is divided in the longitudinal direction into a plurality of rectangular (including square) regions 33. Beam application to a target rectangular region 33 is achieved by collectively deflecting all the multiple primary electron beams 20 by the deflectors 208 and 209.

FIG. 8 shows the case of the multiple primary electron beams 20 of 5 rows by 5 columns. The size of an irradiation region 34 that can be irradiated by one irradiation with the multiple primary electron beams 20 is defined by (the x-direction size obtained by multiplying the x-direction beam pitch of the multiple primary electron beams 20 on the substrate 101 by the number of x-direction beams)×(the y-direction size obtained by multiplying the y-direction beam pitch of the multiple primary electron beams 20 on the substrate 101 by the number of y-direction beams). The irradiation region 34 serves as a field of view of the multiple primary electron beams 20. A sub-irradiation region 29, in which the beam concerned itself is located and which is surrounded by the beam's x-direction beam pitch and y-direction beam pitch, is irradiated and scanned (scanning operation) with each primary electron beam 10 of the multiple primary electron beams 20. Each primary electron beam 10 is associated with any one of the sub-irradiation regions 29 which are different from each other. At the time of each shot, each primary electron beam 10 is applied to the same position in the associated sub-irradiation region 29. The primary electron beam 10 is moved in the sub-irradiation region 29 by collective deflection of all the multiple primary electron beams 20 by the deflectors 208 and 209. By repeating this operation, the inside of one sub-irradiation region 29 is irradiated, in order, with one primary electron beam 10.

Preferably, the width of each stripe region 32 is set to be the same as the y-direction size of the irradiation region 34, or to be the size reduced by the width of the scanning margin. In the case of FIG. 8, the irradiation region 34 and the rectangular region 33 are of the same size. However, it is not limited thereto. The irradiation region 34 may be smaller than the rectangular region 33, or larger than it. Using each primary electron beam 10 of the multiple primary electron beams 20, the sub-irradiation region 29 in which the primary electron beam 10 concerned itself is located is irradiated and scanned (scanning operation) by the primary electron beam 10 concerned. Then, when scanning of one sub-irradiation region 29 is completed, the irradiation position is moved to an adjacent rectangular region 33 in the same stripe region 32 by collectively deflecting all the multiple primary electron beams 20 by the deflectors 208 and 209. By repeating this operation, the stripe region 32 is irradiated in order. After completing scanning of one stripe region 32, the irradiation region 34 is moved to the next stripe region 32 by moving the stage 105 and/or by collectively deflecting all the multiple primary electron beams 20 by the deflectors 208 and 209. As described above, by irradiation with each primary electron beam 10, the scanning operation per sub-irradiation region 29 and acquisition of a secondary electron image are performed. By combining these secondary electron images of respective sub-irradiation regions 29, a secondary electron image of the rectangular region 33, a secondary electron image of the stripe region 32, or a secondary electron image of the inspection region 330 is configured. When an image comparison is actually performed, the sub-irradiation region 29 in each rectangular region 33 is further divided into a plurality of frame regions 30, and then, a comparison is performed with respect to a frame image 31 of each frame region 30. FIG. 8 shows the case of dividing the sub-irradiation region 29, which is scanned with one primary electron beam 10, into four frame regions 30 by halving it in the x and y directions, for example.

In the case of applying the multiple primary electron beams 20 to the substrate 101 while the stage 105 is continuously moving, the deflectors 208 and 209 execute a tracking operation by performing collective deflection so that the irradiation position of the multiple primary electron beams 20 may follow the movement of the stage 105. Therefore, the emission position of the multiple secondary electron beams 300 changes every second with respect to the trajectory central axis of the multiple primary electron beams 20. Similarly, in the case of scanning the sub-irradiation region 29, the emission position of each secondary electron beam changes every second inside the sub-irradiation region 29. The deflector 225 collectively deflects the multiple secondary electron beams 300 so that each secondary electron beam whose emission position has changed may be applied to a corresponding detection region of the multi-detector 222.

As described above, the image acquisition mechanism 150 proceeds with scanning of each stripe region 32. An image (secondary electron image) to be used for inspection is acquired by irradiating the inspection substrate 101 on the stage 105 with the multiple primary electron beams 20, and detecting, by the multi-detector 222, the multiple secondary electron beams 300 emitted from the substrate 101 due to the irradiation with the multiple primary electron beams 20. A reflected electron may be included in detected multiple secondary electron beams 300. Alternatively, a reflected electron may be separated during moving in the secondary electron optical system 152 not to reach the multi-detector 222. Detection data (measured image data: secondary electron image data: inspection image data) on the secondary electron of each pixel in each sub-irradiation region 29, detected by the multi-detector 222, is output to the detection circuit 106 in order of measurement. In the detection circuit 106, the detection data in analog form is converted into digital data by an A-D converter (not shown), and stored in the chip pattern memory 123. Then, acquired measured image data is transmitted to the comparison circuit 108, together with information on each position from the position circuit 107.

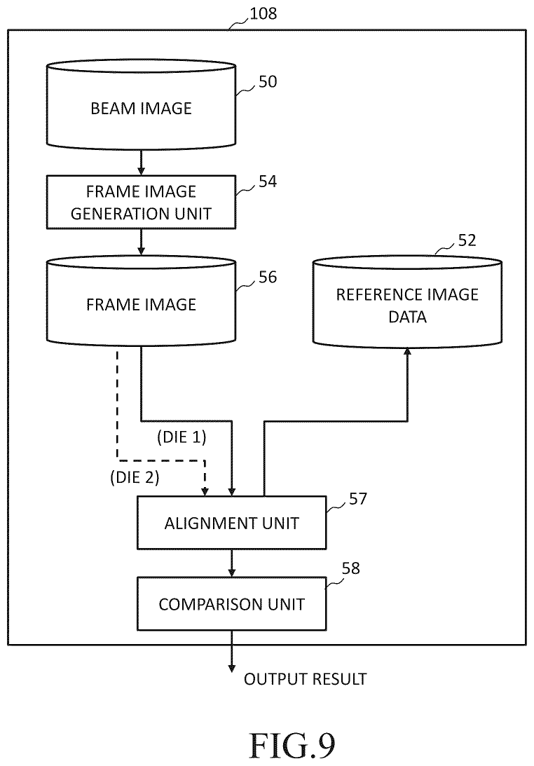

FIG. 9 is a diagram showing an example of an internal configuration of a comparison circuit according to the first embodiment. In FIG. 9, storage devices 50, 52 and 56 such as magnetic disk drives, a frame image generation unit 54, an alignment unit 57, and a comparison unit 58 are arranged in the comparison circuit 108. Each of the “units” such as the frame image generation unit 54, the alignment unit 57 and the comparison unit 58 includes processing circuitry. The processing circuitry includes an electric circuit, a computer, a processor, a circuit board, a quantum circuit, a semiconductor device, or the like. Further, common processing circuitry (same processing circuitry), or different processing circuitry (separate processing circuitry) may be used for each of the “units”. Input data needed in the frame image generation unit 54, the alignment unit 57 and the comparison unit 58, or a calculated result is stored in a memory (not shown) or in the memory 118 each time.

Measured image data (beam image) transmitted into the comparison circuit 108 is stored in the storage device 50.

The frame image generation unit 54 generates the frame image 31 of each of a plurality of frame regions 30 by further dividing image data of the sub-irradiation region 29 acquired by scanning with each primary electron beam 10. The frame region 30 is used as a unit region of an inspection image to be inspected. In order to prevent missing an image, it is preferable that the margin region of each frame region 30 overlaps with each other. The generated frame image 31 is stored in the storage device 56.

On the other hand, the reference image generation circuit 112 generates, for each frame region 30, a reference image corresponding to the frame image 31, based on design data serving as a basis of a plurality of figure patterns formed on the substrate 101. Specifically, it operates as follows: First, design pattern data is read from the storage device 109 through the control computer 110, and each figure pattern defined by the read design pattern data is converted into image data in binary or multiple values.

As described above, basic figures defined by the design pattern data are, for example, rectangles (including squares) and triangles. For example, there is stored figure data which defines the shape, size, position, and the like of each pattern figure by using information, such as coordinates (x, y) of the reference position of the figure, lengths of sides of the figure, and a figure code serving as an identifier for identifying the figure type such as rectangles and triangles.

When design pattern data serving as the figure data is input to the reference image generation circuit 112, the data is developed into data for each figure, and then, the figure code, the figure dimensions, and others indicating the figure shape in each figure data are interpreted. Then, the reference image generation circuit 112 develops each figure data to design pattern image data in binary or multiple values as a pattern to be arranged in squares in units of grids of predetermined quantization dimensions, and outputs the developed data. In other words, the reference image generation circuit 112 reads design data, calculates the occupancy rate of a figure in the design pattern, for each square region obtained by virtually dividing the inspection region into squares in units of predetermined dimensions, and outputs n-bit occupancy rate data. For example, it is preferable to set one square as one pixel. Assuming that one pixel has a resolution of 1/2⁸ (=1/256), the occupancy rate in each pixel is calculated by allocating sub-regions, each having 1/256 resolution, which correspond to the region of a figure arranged in the pixel. Then, it is generated as 8-bit occupancy data. Such square regions (inspection pixels) can be corresponding to (commensurate with) pixels of measured data.

Next, the reference image generation circuit 112 performs filtering processing on design image data of a design pattern which is image data of a figure, using a predetermined filter function. Thereby, it becomes possible to match/fit the design image data being design side image data, whose image intensity (gray scale level) is represented by digital values, with image generation characteristics obtained by irradiation with the multiple primary electron beams 20. Image data for each pixel of a generated reference image is output to the comparison circuit 108. The reference image data transmitted into the comparison circuit 108 is stored in the storage device 52.

Next, the alignment unit 57 reads the frame image 31 serving as an inspection image, and a reference image corresponding to the frame image 31 concerned, and provides alignment between both the images, based on units of sub-pixels smaller than units of pixels. For example, the alignment can be performed by a least squares method.

Then, the comparison unit 58 compares a secondary electron image of the substrate 101 placed on the stage 105 with a predetermined image. Specifically, the comparison unit 58 compares, for each pixel, the frame image 31 and the reference image. The comparison unit 58 compares them, for each pixel, based on predetermined determination conditions in order to determine whether there is a defect such as a shape defect. For example, if a difference in gray scale level for each pixel is larger than a determination threshold Th, it is determined that there is a defect. Then, the comparison result is output. It may be output to the storage device 109 or the memory 118, or alternatively, output from the printer 119.

In the examples described above, the die-to-database inspection is performed. However, it is not limited thereto. A die-to-die inspection may be performed. In the case of the die-to-die inspection, alignment and comparison having been described above are carried out between the frame image 31 (die 1) to be inspected and another frame image 31 (die 2) (another example of a reference image) in which there is formed the same pattern as that of the frame image 31 to be inspected.

According to the first embodiment, as described above, it is possible to suppress discharging between the electromagnetic lens 207 (objective lens) and the substrate 101 (target object).

In the above description, each “ . . . circuit” includes processing circuitry. The processing circuitry includes an electric circuit, a computer, a processor, a circuit board, a quantum circuit, a semiconductor device, or the like. Each “ . . . circuit” may use common processing circuitry (the same processing circuitry), or different processing circuitry (separate processing circuitry). Programs for causing a processor, etc. to execute processing may be stored in a recording medium, such as a magnetic disk drive, magnetic tape drive, FD, ROM (Read Only Memory) or the like. For example, the position circuit 107, the comparison circuit 108, the reference image generation circuit 112, and the like may be formed by at least one processing circuit described above.

Embodiments have been explained referring to specific examples described above. However, the present invention is not limited to these specific examples.

While the apparatus configuration, control method, and others not directly necessary for explaining the present invention are not described, some or all of them can be appropriately selected and used on a case-by-case basis when needed.

Any electromagnetic lens, scanning electron microscope, and multi-electron beam inspection apparatus that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An electromagnetic lens comprising:
a coil;
a yoke, made of magnetic material, configured to include an upper wall on an upstream side with respect to an advancing direction of a primary electron beam passing, an outer peripheral wall, an inner peripheral wall, and one of a lower wall in which a gap is formed on a downstream side with respect to the advancing direction of the primary electron beam and an inclined wall in which a gap is formed on a downstream side with respect to the advancing direction of the primary electron beam, configured to let the primary electron beam pass through a space surrounded by the inner peripheral wall, and configured to surround the coil by the upper wall, the outer peripheral wall, the inner peripheral wall, and the one of the lower wall and the inclined wall; and
a cover, made of a non-magnetic conductor, configured to contact and cover an end surface of the yoke on the downstream side with respect to the advancing direction of the primary electron beam, the end surface including a corner portion on an inner peripheral side, wherein a corner portion of the cover is formed to have a curved surface.

2. The electromagnetic lens according to claim 1, wherein
a substrate to be irradiated with the primary electron beam and applied with a retarding potential is arranged on the downstream side, with respect to the advancing direction of the primary electron beam, of the electromagnetic lens, and
a radius of curvature of the curved surface at the corner portion of the cover is set such that an electric field strength at the corner portion of the cover is one of equal to and less than a threshold value in a state where a ground potential has been applied to the yoke and the retarding potential has been applied to the substrate.

3. The electromagnetic lens according to claim 1, wherein the cover includes
a first covering member which covers an end surface of the inner peripheral wall, on the downstream side with respect to the advancing direction of the primary electron beam, and
a second covering member which covers an end surface of one of the lower wall and the inclined wall on the downstream side with respect to the advancing direction of the primary electron beam, the end surface of the one of the lower wall and the inclined wall including the corner portion on the inner peripheral side.

4. The electromagnetic lens according to claim 1, wherein
the cover covers a portion of an inner peripheral surface of the yoke, continuous from the end surface on the downstream side with respect to the advancing direction of the primary electron beam, and
a first thickness which covers the portion of the inner peripheral surface is thicker than a second thickness which covers the end surface on the downstream side.

5. The electromagnetic lens according to claim 3, wherein
the second covering member covers a portion of an inner peripheral surface of the one of the lower wall and the inclined wall, continuous from the end surface on the downstream side with respect to the advancing direction of the primary electron beam, and
a first thickness of the second covering member which covers the portion of the inner peripheral surface is thicker than a second thickness of the second covering member which covers the end surface on the downstream side.

6. The electromagnetic lens according to claim 3, wherein
the first covering member covers a portion of an inner peripheral surface continuous from the end surface of the inner peripheral wall on the downstream side with respect to
the advancing direction of the primary electron beam, and the second covering member covers a portion of an inner peripheral surface continuous from the end surface of the one of the lower wall and the inclined wall, on the downstream side with respect to the advancing direction of the primary electron beam.

7. The electromagnetic lens according to claim 6, wherein a thickness of the first covering member, which covers the end surface on the downstream side, is a same as a thickness of the second covering member, which covers the end surface on the downstream side.

8. The electromagnetic lens according to claim 6, wherein a thickness of the first covering member, which covers the portion of the inner peripheral surface, is a same as a thickness of the second covering member, which covers the portion the inner peripheral surface.

9. The electromagnetic lens according to claim 6, wherein a thickness of the first covering member, which covers the portion of the inner peripheral surface, is different from a thickness of the second covering member, which covers the portion of the inner peripheral surface.

10. A scanning electron microscope comprising:
an electromagnetic lens configured to include
a coil,
a yoke, made of magnetic material, which includes an upper wall on an upstream side with respect to an advancing direction of a primary electron beam passing, an outer peripheral wall, an inner peripheral wall, and one of a lower wall in which a gap is formed on a downstream side with respect to the advancing direction of the primary electron beam and an inclined wall in which a gap is formed on a downstream side with respect to the advancing direction of the primary electron beam, which is configured to let the primary electron beam pass through a space surrounded by the inner peripheral wall, and which surrounds the coil by the upper wall, the outer peripheral wall, the inner peripheral wall, and the one of the lower wall and the inclined wall, and
a cover, made of a non-magnetic conductor, which contacts and covers an end surface of the yoke on the downstream side with respect to the advancing direction of the primary electron beam, the end surface of the yoke including a corner portion on an inner peripheral side, wherein the corner portion of the cover is formed to have a curved surface;
a stage configured to place thereon a target object which is to be irradiated with the primary electron beam having passed through the electromagnetic lens; and
a detector configured to detect a secondary electron beam emitted from the target object.

11. An electron beam inspection apparatus comprising:
an electromagnetic lens configured to include
a coil,
a yoke, made of magnetic material, which includes an upper wall on an upstream side with respect to an advancing direction of a primary electron beam passing, an outer peripheral wall, an inner peripheral wall, and one of a lower wall in which a gap is formed on a downstream side with respect to the advancing direction of the primary electron beam and an inclined wall in which a gap is formed on a downstream side with respect to the advancing direction of the primary electron beam, which is configured to let the primary electron beam pass through a space surrounded by the inner peripheral wall, and which surrounds the coil by the upper wall, the outer peripheral wall, the inner peripheral wall, and the one of the lower wall and the inclined wall, and
a cover, made of a non-magnetic conductor, which contacts and covers an end surface of the yoke on the downstream side with respect to the advancing direction of the primary electron beam, the end surface of the yoke including a corner portion on an inner peripheral side, wherein the corner portion of the cover is formed to have a curved surface;
a stage configured to place thereon a target object which is to be irradiated with the primary electron beam having passed through the electromagnetic lens; and
a detector configured to detect a secondary electron beam emitted from the target object.
